(19) United States
(12) Patent Application Publication
(10) Pub. No.: US 2018/0228054 A1
(43) Pub. Date: Aug. 9, 2018

(54) HEATSINK WITH NANOTWINNED COPPER WALL

(71) Applicant: Dyi-Chung HU, Hsinchu (TW)

(72) Inventor: Dyi-Chung HU, Hsinchu (TW)

(21) Appl. No.: 15/943,727

(22) Filed: Apr. 3, 2018

Related U.S. Application Data
(62) Division of application No. 15/346,799, filed on Nov. 9, 2016.
(60) Provisional application No. 62/255,207, filed on Nov. 13, 2015.

(51) Int. Cl. H05K 7/20; F28F 3/02; F28F 21/08; F28F 9/007

(52) U.S. Cl. CPC H05K 7/20254; F28F 2255/20; F28F 3/022; F28F 9/0075; F28F 21/085; H05K 7/2039

(57) ABSTRACT

A heatsink fabricated through metal plating is disclosed. The heatsink is built to have at least a nanotwinned copper wall. A top metal sheet is directly bonded onto a top surface of the nanotwinned copper wall at a temperature roughly between 150˜250 degree Celsius.

### CROSS-REFERENCE TO RELATED APPLICATIONS

This application is a divisional application of and claims the priority benefit of U.S. application Ser. No. 15/346,799, filed on Nov. 9, 2016, now pending, which claims the priority benefit to U.S. provisional application Ser. No. 62/255,207, filed on Nov. 13, 2015. The entirety of each of the above-mentioned patent applications is hereby incorporated by reference herein and made a part of specification.

### BACKGROUND

### Technical Field

The present invention relates to a heatsink; especially relates to a high strength Heatsink with Nanotwinned Copper Wall.

### Description of Related Art

FIG. 1 Shows a Prior Art.

FIG. 1 shows a first prior art U.S. Pat. No. 8,441,794 where an aluminum (Al) heatsink is disclosed. The aluminum heatsink has a plurality of internal fins 112 and a cavity 118. The aluminum heatsink is fabricated by metal extrusion because of the ductility feature for aluminum.

The heat sink comprises an inlet conduit 130 and an outlet conduit 132 for the cooling liquid and a plurality of liquid channels serving as supply 120 and return 122 passages for the liquid. The inlet and outlet conduit 130, 132 may be of circular cross section or may have any other shape. Preferably the inlet and outlet conduits are of a different shape than the other conduits. The liquid channels serving as said supply and return passages 120, 122 are formed by creating during extrusion at least two internal cavities provided with a plurality of internal fins 112 directed into and along the cavities respectively. The fins 112 extends the cooling surface and gives a more efficient cooling than would a single passage having the same cross sectional area.

The channels 20, 22 formed in one cavity 18 are separated from the channels 20, 22 formed in a neighbouring cavity 18 by dividing walls 16, whereby a serpentine cooling system of the channels formed in the cavities is accomplished. The formation of the channels 20, 22 of a cavity 18 is established by an insert 14 being introduced into the central part of the cavity along its extension, whereby the tops of the fins 12 are blocked in a fluid-tight manner and said channels 20, 22 for the liquid is formed between the insert 14 and the hollow body 10. The fins 12 form internal walls of the liquid channels.

A second prior art, U.S. Pat. No. 8,557,507 shows a Fabrication of Nanotwinned Nonapillars where no heatsink has been disclosed.

### BRIEF DESCRIPTION OF THE DRAWINGS

FIG. 1 shows a prior art.

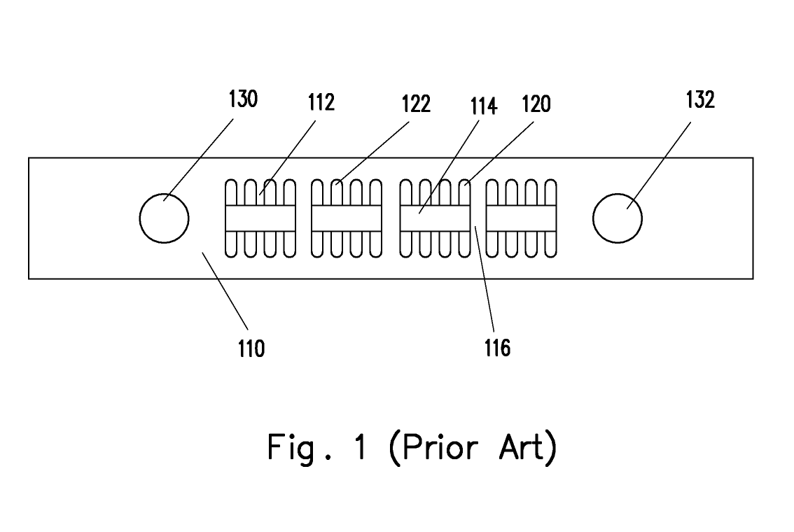

FIGS. 2A˜2E shows a fabricating process according to the present invention.

FIGS. 3A˜3B show a section views for a product of FIG. 2E.

FIG. 4 shows a modified heatsink according to the present invention.

### DETAILED DESCRIPTION OF THE INVENTION

Metals with a high density of nanometre-scale twins have demonstrated simultaneous high strength and good ductility, attributed to the interaction between lattice dislocations and twin boundaries. Nature Communications 6, Article number: 7648 doi:10.1038/ncomms8648

Direct Cu-to-Cu bonding was achieved at temperatures of 150-250° C. using a compressive stress of 100 psi (0.69 MPa) held for 10-60 min at 10(−3) torr. The key controlling parameter for direct bonding is rapid surface diffusion on (111) surface of Cu. Instead of using (111) oriented single crystal of Cu, oriented (111) texture of extremely high degree, exceeding 90%, was fabricated using the oriented nano-twin Cu. The bonded interface between two (111) surfaces forms a twist-type grain boundary. Scientific reports 15:09734 DOI:10.1038/srep09734.

TABLE 1
Surface Diffusivity (cm²/sec) for Cu lattice 111 oriented, Cu
(100), and Cu (110):

| D_{surf.}\Temp. | (111) | (100) | (110) |
|---|---|---|---|
| 300° C. | 1.51 × 10⁻⁵ | 1.48 × 10⁻⁸ | 1.55 × 10⁻⁹ |
| 250° C. | 1.22 × 10⁻⁵ | 4.74 × 10⁻⁹ | 3.56 × 10⁻¹⁰ |
| 200° C. | 9.42 × 10⁻⁶ | 1.19 × 10⁻⁹ | 5.98 × 10⁻¹¹ |
| 150° C. | 6.85 × 10⁻⁶ | 2.15 × 10⁻¹⁰ | 6.61 × 10⁻¹² |

*Agrawal, P. M. et al. Predicting trends in rate parameters for self-diffusion on FCC metal surfaces. Surf. Sci. 515, 21-35 (2003).

At 300° C., a surface diffusivity of 1.51×10⁻⁵ for Cu(111) is roughly one thousand times than 1.48×10⁻⁸ for Cu (100), and roughly ten thousand times than 1.55×10⁻⁹ for Cu (110).

At 250° C., a surface diffusivity of 1.22×10⁻⁵ for Cu(111) is roughly ten thousand times than 4.74×10⁻⁹ for Cu (100), and roughly one hundred thousand times than 3.56×10⁻¹⁰ for Cu (110).

At 200° C., a surface diffusivity of 9.42×10⁻⁶ for Cu(111) is roughly one thousand times than 1.19×10⁻⁹ for Cu (100), and roughly one hundred thousand times than 5.98×10⁻¹⁰ for Cu (110).

At 150° C., a surface diffusivity of 6.85×10⁻⁶ for Cu(111) is roughly ten thousand times than 2.15×10⁻¹⁰ for Cu (100), and roughly one million times than 6.61×10⁻¹² for Cu (110).

With the above information, a high strength heatsink made with nanotwinned copper is disclosed according to the present invention.

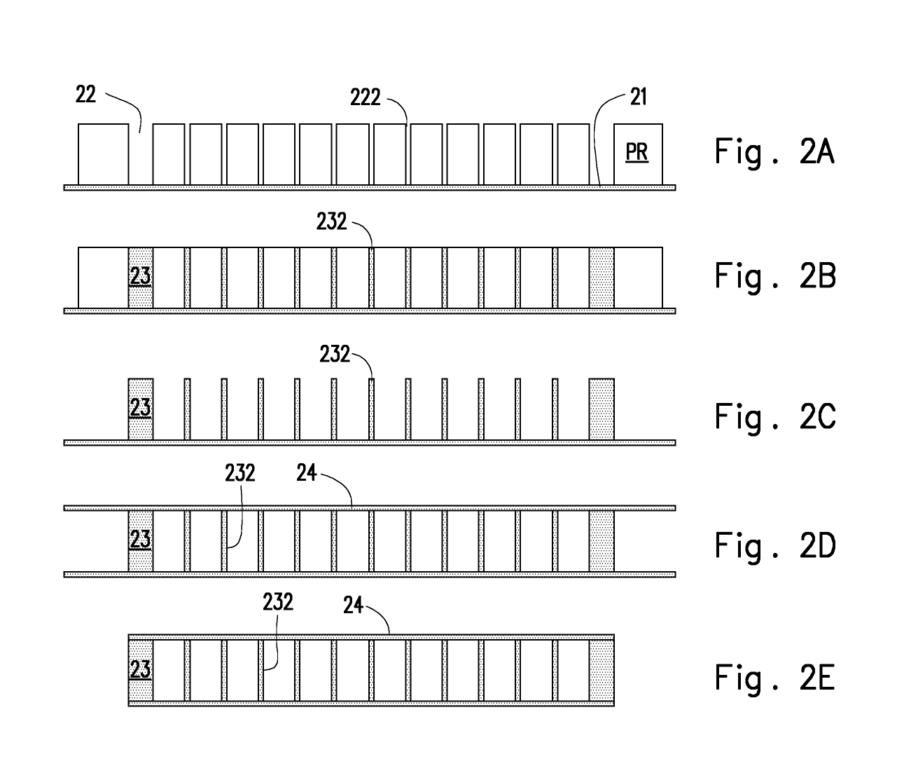

FIGS. 2A˜2E Shows a Fabricating Process According to the Present Invention.

FIG. 2A shows: applying a patterned photoresist PR on a top surface of a bottom copper sheet 21; where a rectangular trenches 22 for building a peripheral wall and a plurality of trenches 222 for building copper pillars are formed. A top surface of the copper sheet 21 is exposed on each bottom of the trenches 22, 222;

FIG. 2B shows: plating to form a nanotwinned copper wall 23 and a plurality of nanotwinned copper pillars 232;

FIG. 2C shows: stripping the photoresist PR;

FIG. 2D shows: bonding a top copper sheet 24 directly on a top surface of the copper wall 23 and the plurality of copper pillars 232, through copper to copper direct bonding (Cu-to-Cu bonding); and

FIG. 2E shows: trimming to form a heat sink with nanotwinned copper wall 23 and a plurality of nanotwinned copper pillars 232 enclosed by the nanotwinned copper wall 23.

The Copper bonding for the top copper sheet 24 bonded to the wall copper 23 and to the plurality of copper pillars 232 is copper to copper direct bonding under a temperature between 150˜250 Celsius degree.

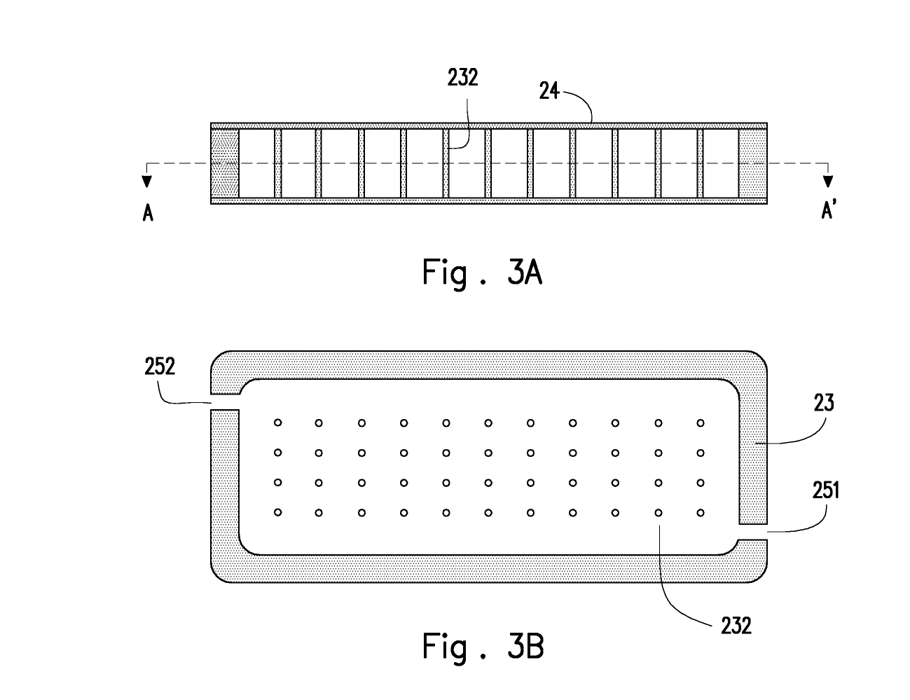

FIGS. 3A˜3B Show a Section Views for a Product of FIG. 2E.

FIG. 3A shows the same product of FIG. 2E, which shows a side perspective view of a first embodiment according to the present invention.

FIG. 3B shows a section view according to line AA′ of FIG. 3A.

FIG. 3B shows a plurality of nanotwinned copper pillars 232 are formed within the heatsink and enclosed by the nanotwinned copper wall 23; each of the copper pillars has a top end directly bonded to the top copper sheet 24.

A first opening 251 and a second opening 252 are formed passing through the copper wall 23. During operation of the heatsink, a coolant 26 (not shown) passes the heatsink to carry away heat generated from an electronic device (not shown) attached to the heatsink. The first opening 251 can be an entrance for the coolant to flow in and the second opening 252 can be an exit for the coolant to flow out. The plurality of copper pillars 232 are disturbs to homogenize the coolant (not shown).

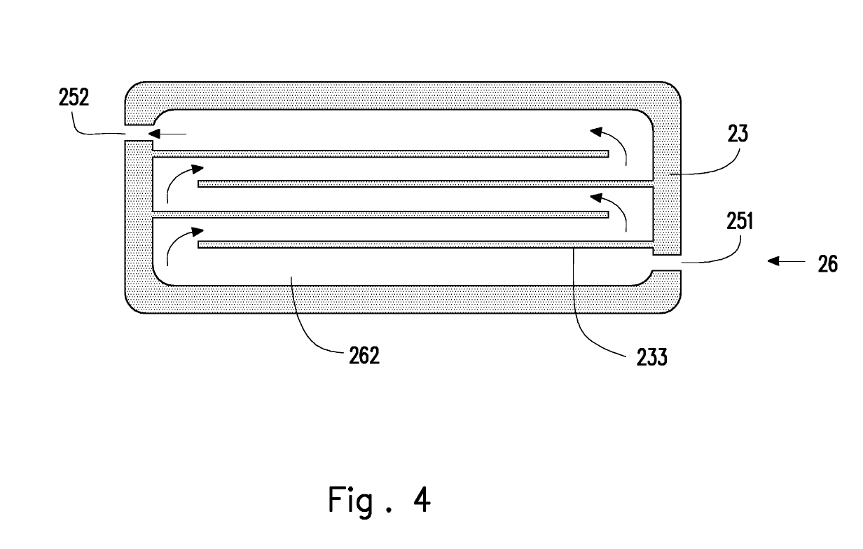

FIG. 4 Shows a Modified Heatsink According to the Present Invention.

FIG. 4 shows a plurality of nanotwinned copper partitions 233 formed within the heatsink. The plurality of copper partitions 233 are enclosed by the nanotwinned copper wall 23. A passage 262 is formed by the partitions 233 and the wall 23 for the coolant (not shown) to flow. Each of the nanotwinned copper partitions 233 has a top end directly bonded to the top copper sheet 24 through direct copper to copper bonding.

While several embodiments have been described by way of example, it will be apparent to those skilled in the art that various modifications may be configured without departs from the spirit of the present invention. Such modifications are all within the scope of the present invention, as defined by the appended claims.

Numerical system

```
21, 24 copper sheet
22, 222 trenches
  23 copper wall
232 copper pillars
233 copper partitions
251, 252 opening
  26 coolant
262 passage
```

What is claimed is:

1. A heatsink with a nanotwinned copper wall, comprising:
a bottom copper sheet;
a nanotwinned copper wall, configured on a top surface of the bottom copper sheet;
a top copper sheet, directly bonded on a top surface of the nanotwinned copper wall; and
a plurality of nanotwinned copper partitions, configured on a top surface of the bottom copper sheet, enclosed by the nanotwinned copper wall.

2. A heatsink as claimed in claim 1, wherein each of the nanotwinned copper partitions has a top end directly bonded to the top copper sheet.

3. A heatsink as claimed in claim 1, wherein the nanotwinned copper is with copper lattice 111 oriented.

4. A heatsink as claimed in claim 2,
wherein the nanotwinned copper wall comprises:
a first wall part;
a second wall part that faces the first wall part;
a third wall part that intersects the first wall part and the second wall part; and
a fourth wall part that intersects the first wall part and the second wall part, and faces the third wall part; and
the nanotwinned copper partitions comprises:
a plurality of first nanotwinned copper partitions coupled to the first wall part; and
a plurality of second nanotwinned copper partitions coupled to the second wall part.

5. A heatsink as claimed in claim 4, wherein the plurality of first nanotwinned copper partitions and the plurality of second nanotwinned copper partitions are arranged in parallel.

6. A heatsink as claimed in claim 4, wherein a number of the plurality of first nanotwinned copper partitions is equal to a number of the plurality of second nanotwinned copper partitions.

7. A heatsink as claimed in claim 4, wherein the plurality of first nanotwinned copper partitions and the plurality of second nanotwinned copper partitions are arranged in an interlaced configuration.

8. A heatsink as claimed in claim 7, wherein:
the first wall part includes a first opening passing through the first wall part;
the second wall part includes a second opening passing through the second wall part; and
the bottom copper sheet, the top copper sheet, the nanotwinned copper wall and the plurality of nanotwinned copper partitions form a container that allows a fluid inject to pass through the first opening and the second opening.

9. A heatsink as claimed in claim 8, wherein the fluid is coolant.

10. A heatsink as claimed in claim 8, wherein the fluid has a single direction of flow in the container.

11. A heatsink as claimed in claim 10, wherein the single direction of flow does not divide.
